(19) United States
(12) Patent Application Publication
(10) Pub. No.: US 2025/0167581 A1
(43) Pub. Date: May 22, 2025

(54) SECONDARY BATTERY CHARGE/DISCHARGE TEST SYSTEM AND METHOD THEREOF

(71) Applicant: SK On Co., Ltd., Seoul (KR)

(72) Inventor: Chang Mook HWANG, Daejeon (KR)

(21) Appl. No.: 18/925,037

(22) Filed: Oct. 24, 2024

(30) Foreign Application Priority Data
Nov. 16, 2023 (KR) 10-2023-0159024

(51) Int. Cl. H02J 7/00; G01R 31/388

(52) U.S. Cl. CPC H02J 7/007182; G01R 31/388; H02J 7/0013; H02J 7/0048

(57) ABSTRACT

Provided is a secondary battery charge/discharge test system including: a test power storage device for charging or discharging a plurality of test secondary batteries; an auxiliary power storage device for charging the test power storage device by discharging power stored therein or being charged using power discharged by the test power storage device; and a control unit for controlling the charge or discharge of each of the auxiliary power storage device and the test power storage device based on the state of charge (SOC) or cut-off voltage of the auxiliary power storage device.

### CROSS-REFERENCE TO RELATED APPLICATIONS

This application claims priority under 35 U.S.C. § 119 to Korean Patent Application No. 10-2023-0159024, filed on Nov. 16, 2023, in the Korean Intellectual Property Office, the disclosure of which is incorporated herein by reference in its entirety.

### TECHNICAL FIELD

The following disclosure relates to a system and a method for testing charge/discharge performance of a secondary battery.

### BACKGROUND

There is an increasing demand for a secondary battery, which may reduce the use of fossil fuels, in accordance with an increased interest in eco-friendly energy. The secondary battery may reduce the use of fossil fuels and increase energy efficiency through its repeated use.

The secondary battery may be used by being charged through a separate power device. The secondary battery may be discharged to supply electric energy stored therein to the outside. A charge/discharge test may be essential during a development stage of the secondary battery to improve its performance.

All power stored in the secondary battery may be discharged during the discharge test in the secondary battery charge/discharge test. All discharged power may be generally discarded. During the charge test, power may then be supplied from an external power network again to thus charge the secondary battery.

### RELATED ART DOCUMENT

### Patent Document

Japanese Patent No. JP 5433368 B2 (Dec. 13, 2013)

### SUMMARY

An embodiment of the present disclosure is directed to providing a secondary battery charge/discharge test system that may increase energy efficiency in a charge/discharge test of a secondary battery by recycling electric energy discarded during the discharge in the test, and a method thereof.

In one general aspect, provided is a secondary battery charge/discharge test system including: a test power storage device for charging or discharging a plurality of test secondary batteries; an auxiliary power storage device for charging the test power storage device by discharging power stored therein or being charged using power discharged by the test power storage device; and a control unit for controlling the charge or discharge of each of the auxiliary power storage device and the test power storage device based on the state of charge (SOC) or cut-off voltage of the auxiliary power storage device.

The control unit may stop the discharge of the auxiliary power storage device and charge the auxiliary power storage device by using power from an external power network when the state of charge of the auxiliary power storage device is less than a set value.

The control unit may charge the test power storage device by discharging the auxiliary power storage device when the state of charge of the auxiliary power storage device is the set value or more.

The control unit may stop the discharge of the auxiliary power storage device and charge the auxiliary power storage device by discharging the test power storage device when the auxiliary power storage device reaches the preset discharge cut-off voltage.

The control unit may charge the test power storage device to the preset charge cut-off voltage of the test power storage device by using power of the external power network, and then charge the auxiliary power storage device by discharging the test power storage device.

The control unit may charge the auxiliary power storage device by discharging the test power storage device when the state of charge of the auxiliary power storage device is the set value or more of the state of charge and less than a complete state of charge.

The control unit may discharge remaining power of the test power storage device by bypassing the auxiliary power storage device when the state of charge of the auxiliary power storage device is the complete state of charge.

The control unit may stop the discharge of the auxiliary power storage device and charge the auxiliary power storage device by discharging the test power storage device when the auxiliary power storage device does not reach the preset discharge cut-off voltage and the state of charge of the auxiliary power storage device is not a complete discharge state.

The control unit may charge the auxiliary power storage device by using the external power network when the auxiliary power storage device does not reach the preset cut-off voltage and the state of charge of the auxiliary power storage device is the complete discharge state.

In another general aspect, provided is a secondary battery charge/discharge test method, in which a charge/discharge test of a test power storage device is performed by connecting the test power storage device including a plurality of test secondary batteries to a separate auxiliary power storage device, and controlling, by a control unit, the charge and discharge of each of the test power storage device and the auxiliary power storage device, the method including: monitoring a state of charge of the auxiliary power storage device; performing the charge test of charging the test power storage device by discharging the auxiliary power storage device when the state of charge of the auxiliary power storage device is a set value or more of the state of charge; and performing the discharge test of charging the auxiliary power storage device by discharging the test power storage device when the auxiliary power storage device reaches the preset cut-off voltage in the charge test.

In the monitoring, the auxiliary power storage device may be charged to the set value or more of the state of charge by using power of an external power network when the state of charge of the auxiliary power storage device is less than the set value.

In the performing of the discharge test, the auxiliary power storage device may be charged using the external power network when the auxiliary power storage device does not reach the preset cut-off voltage and is in a complete discharge state.

In the performing of the discharge test, the test power storage device may be charged using power from the external power network when the test power storage device does not reach its preset cut-off voltage, and the auxiliary power storage device may then be charged by discharging the test power storage device.

In the performing of the discharge test, the monitoring may be repeated when the state of charge of the auxiliary power storage device is not a complete state of charge.

In the performing of the discharge test, remaining power of the test power storage device may be discharged by bypassing the auxiliary power storage device when the state of charge of the auxiliary power storage device is a complete state of charge.

Other features and aspects will be apparent from the following detailed description, the drawings, and the claims.

### BRIEF DESCRIPTION OF THE DRAWINGS

FIG. 1 is a schematic view of a secondary battery charge/discharge test system according to one embodiment.

FIG. 2 is a flow chart showing a process of a secondary battery charge/discharge test method according to one embodiment.

FIG. 3 is a flow chart showing the flow chart of FIG. 2 in detail.

### DETAILED DESCRIPTION OF EMBODIMENTS

Hereinafter, embodiments of the present disclosure are described in detail with reference to the accompanying drawings. However, the embodiments are merely examples, and the present disclosure is not limited to the specific embodiments described illustratively.

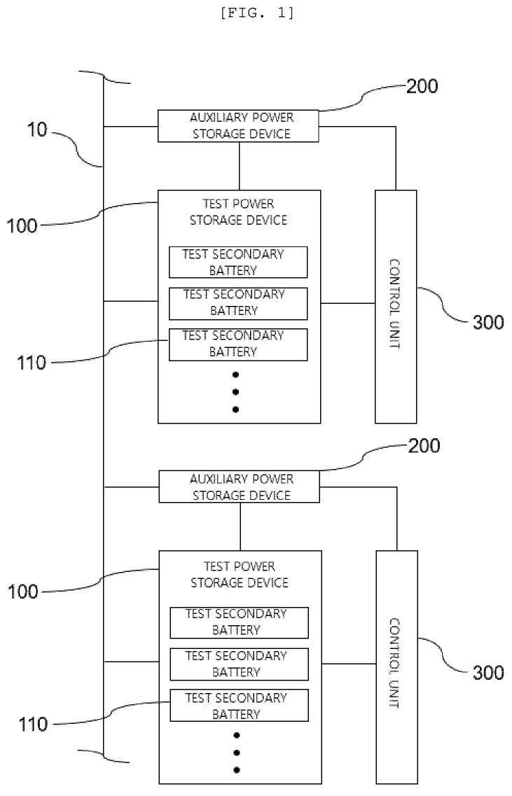

Referring to FIG. 1, a secondary battery charge/discharge test system of the present disclosure may include a test power storage device 100, an auxiliary power storage device 200, and a control unit 300.

The test power storage device 100 may include a plurality of test secondary batteries 110. The test secondary battery 110 may include rechargeable lithium ion batteries, lithium polymer batteries, nickel cadmium batteries, nickel hydrogen batteries, or nickel zinc batteries, and may not limited to a particular type. For example, each of the plurality of test secondary batteries 110 may be a pouch type battery cell. However, the plurality of test secondary batteries 110 is not limited to this type, and in some embodiments, each of the plurality of test secondary batteries 110 may be a battery module or battery pack unit.

The test power storage device 100 may include a chamber that accommodates the plurality of test secondary batteries 110. The plurality of test secondary batteries 110 may be connected in series or in parallel to each other in the chamber. In addition, the chamber may configure an environment for charging and discharging the plurality of test secondary batteries 110 provided with a battery management system (BMS).

The test power storage device 100 may include the plurality of test secondary batteries 110 and simultaneously or individually charge or discharge the batteries 110.

The auxiliary power storage device 200 may be separately connected to the test power storage device 100 for the charge/discharge test of the test power storage device 100. The auxiliary power storage device 200 may include the secondary battery capable of being charged/discharged. In an embodiment, the secondary battery included in the auxiliary power storage device 200 may be of the same type as the plurality of test secondary batteries 110, and is not limited to.

The auxiliary power storage device 200 may charge the test power storage device 100 by discharging power stored therein or may be charged using power discharged by the test power storage device 100. The auxiliary power storage device 200 may discharge power to the test power storage device 100 during the charge test of the test power storage device 100, and may be charged using power stored in the test power storage device 100 during the discharge test of the test power storage device 100.

The auxiliary power storage device 200 may recycle power of the test power storage device 100 without discarding the same during the discharge test.

The test power storage device 100 and the auxiliary power storage device 200 may also be connected to an external power network 10. The external power network 10 may supplement insufficient power due to a loss caused by the charge/discharge of the test power storage device 100 and the auxiliary power storage device 200.

The control unit 300 may control the charge and discharge of each of the test power storage device 100 and the auxiliary power storage device 200. During the charge test of the test power storage device 100, the control unit 300 may transmit a discharge signal to the auxiliary power storage device 200 for the auxiliary power storage device 200 to charge the test power storage device 100. During the discharge test of the test power storage device 100, the control unit 300 may transmit the discharge signal to the test power storage device 100 for the test power storage device 100 to charge the auxiliary power storage device 200.

The control unit 300 may control the charge or discharge of each of the auxiliary power storage device 200 and the test power storage device 100 based on the state of charge (SOC) or cut-off voltage of the auxiliary power storage device 200.

The state of charge may be a value that expresses an amount of power charged in the secondary battery as a total capacity compared to a current amount of power. In general, the state of charge may be expressed as a percentage (%) with 0% indicating a complete discharge and 100% indicating a complete charge. The discharge cut-off voltage is to prevent over-discharge of the secondary battery, and the charge cut-off voltage is to prevent over-charge of the secondary battery.

Each of the auxiliary power storage device 200 and the test power storage device 100 may include the battery management system (BMS, not shown). The BMS may monitor each state of the secondary batteries in the auxiliary power storage device 200 and the test power storage device 100, and transmit information on the state of charge or the cut-off voltage to the control unit 300.

The control unit 300 may stop the discharge of the auxiliary power storage device 200 and charge the auxiliary power storage device 200 by using power from the external power network 10 when the state of charge of the auxiliary power storage device 200 is less than a set value.

The control unit 300 may receive the state of charge of the auxiliary power storage device 200 through the BMS of the auxiliary power storage device 200.

The control unit 300 may stop the auxiliary power storage device 200 from charging the test power storage device 100 by being discharged when the state of charge of the auxiliary power storage device 200 is less than the set value. The control unit 300 may charge the auxiliary power storage device 200 to the set value or more of the state of charge by using the external power network 10. It is preferable that the set value for the state of charge of the auxiliary power storage device 200 is 80%.

The control unit 300 may charge the test power storage device 100 by discharging the auxiliary power storage device 200 when the state of charge of the auxiliary power storage device 200 is the set value or more.

The control unit 300 may transmit the discharge signal to the auxiliary power storage device 200 for the auxiliary power storage device 200 to charge the test power storage device 100 for the charge test of the test power storage device 100 when the state of charge of the auxiliary power storage device 200 is the set value or more.

The control unit 300 may stop the discharge of the auxiliary power storage device 200 and charge the auxiliary power storage device 200 by discharging the test power storage device 100 when the auxiliary power storage device 200 reaches the preset discharge cut-off voltage. Here, it is preferable that the discharge cut-off voltage is set to 2.5 V.

Here, the control unit 300 may charge the test power storage device 100 to the preset charge cut-off voltage of the test power storage device 100 by using power of the external power network 10, and then charge the auxiliary power storage device 200 by discharging the test power storage device 100.

The control unit 300 may monitor the charge cut-off voltage of the test power storage device 100 to enable the discharge test of the test power storage device 100. In addition, the control unit 300 may supplement insufficient power by using the external power network 10 if the test power storage device 100 is not at a charge cut-off voltage level.

The control unit 300 may charge the auxiliary power storage device 200 by discharging the test power storage device 100 when the state of charge of the auxiliary power storage device 200 is the set value or more of the state of charge and less than a complete state of charge.

The control unit 300 may perform control to discharge the test power storage device 100 to thus perform the charge test for charging the auxiliary power storage device 200 when the state of charge of the auxiliary power storage device 200 has a value between the set value of the state of charge and the complete state of charge.

The control unit 300 may discharge remaining power of the test power storage device 100 by bypassing the auxiliary power storage device 200 when the state of charge of the auxiliary power storage device 200 is the complete state of charge. In this case, the control unit 300 may prevent remaining power from being transmitted to the auxiliary power storage device 200. That is, the control unit 300 may stop the charge/discharge test of the test power storage device 100, which is performed while the auxiliary power storage device 200 and the test power storage device 100 exchange power with each other.

The control unit 300 may stop the discharge of the auxiliary power storage device 200 and charge the auxiliary power storage device 200 by discharging the test power storage device 100 when the auxiliary power storage device 200 does not reach the preset discharge cut-off voltage and the state of charge of the auxiliary power storage device 200 is not a complete discharge state.

In addition, the control unit 300 may charge the auxiliary power storage device 200 by using the external power network 10 when the auxiliary power storage device 200 does not reach the preset cut-off voltage and the state of charge of the auxiliary power storage device 200 is the complete discharge state.

The control unit 300 may selectively charge the auxiliary power storage device 200 through the test power storage device 100 or the external power network 10 based on the state of charge of the auxiliary power storage device 200. Here, the control unit 300 may also charge the test power storage device 100 by using power of the auxiliary power storage device 200 simultaneously.

In addition, the control unit 300 may stop the charge/discharge of the auxiliary power storage device 200 or the test power storage device 100 when the auxiliary power storage device 200 does not reach the preset cut-off voltage and the state of charge of the auxiliary power storage device 200 is the complete discharge state. In this case, the control unit 300 may stop the charge/discharge test through an emergency stop.

Hereinafter, the description describes a secondary battery charge/discharge test method of the present disclosure. Omitted is a redundant description of the component included in the secondary battery charge/discharge test system of the present disclosure described above.

In the secondary battery charge/discharge test method of the present disclosure, the charge/discharge test of the test power storage device 100 may be performed by connecting the test power storage device 100 including the plurality of test secondary batteries 110 to the separate auxiliary power storage device 200, and controlling, by the control unit, the charge and discharge of each of the test power storage device 100 and the auxiliary power storage device 200.

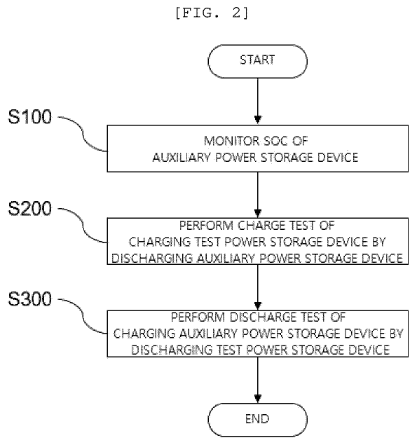

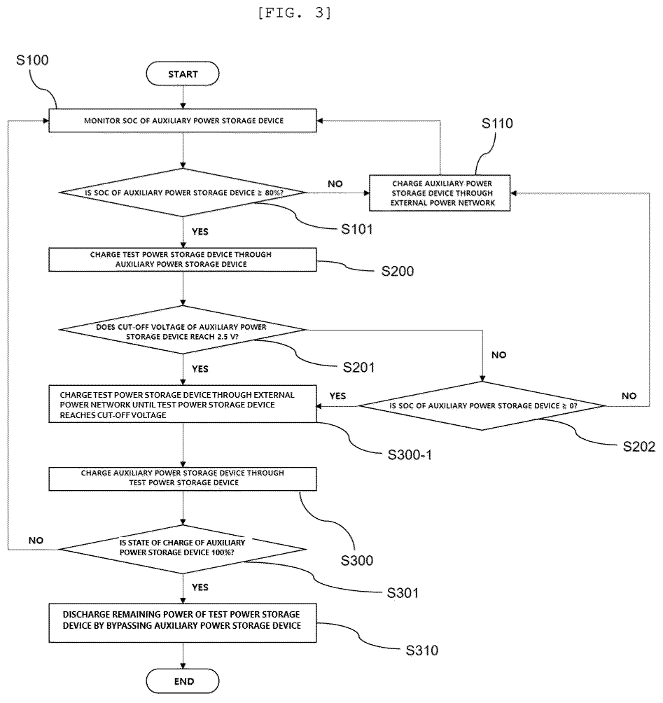

Referring to FIGS. 2 and 3, the secondary battery charge/discharge test method of the present disclosure includes: monitoring the state of charge of the auxiliary power storage device (S100); performing the charge test of charging the test power storage device by discharging the auxiliary power storage device (S200); and performing the discharge test of charging the auxiliary power storage device by discharging the test power storage device (S300).

In step S100, the control unit 300 may monitor the state of charge of the auxiliary power storage device 200 before performing the charge/discharge test.

In step S110, the control unit 300 may charge the auxiliary power storage device 200 to the set value or more of the state of charge by using power of the external power network 10 when the state of charge of the auxiliary power storage device 200 is less than the set value as a result of monitoring by the control unit 300.

In step S101, the control unit 300 may determine whether the state of charge of the auxiliary power storage device 200 is equal to, greater than, or less than the set value of the state of charge. In addition, the control unit 300 may proceed to step S110 if the state of charge of the auxiliary power storage device 200 is less than the set value of the state of charge.

The control unit 300 may proceed to the performing of the charge test (S200) when the state of charge of the auxiliary power storage device 200 is determined to be the set value or more of the state of charge in step S101.

In step S200, the control unit 300 may charge the test power storage device 100 by discharging the auxiliary power storage device 200. In step S200, the performing of the charge test may be performed until the auxiliary power storage device 200 reaches the preset cut-off voltage (S201).

The control unit 300 may proceed to step S300 when the auxiliary power storage device 200 reaches the preset cut-off voltage. In step S300, the control unit 300 may charge the auxiliary power storage device 200 by discharging the test power storage device 100.

Here, the auxiliary power storage device 200 stops its discharging when the auxiliary power storage device 200 does not reach the preset cut-off voltage in step S201 and is in the complete discharge state in step S202. In addition, the control unit 300 may charge the auxiliary power storage device 200 by using the external power network 10.

In addition, the control unit 300 may stop the auxiliary power storage device 200 through the emergency stop.

In step S300, the control unit 300 may charge the test power storage device 100 by using power from the external power network 10 (S300-1) when the test power storage device 100 does not reach its preset cut-off voltage. The control unit 300 may then charge the auxiliary power storage device 200 by discharging the test power storage device 100. The control unit 300 may enable the test power storage device 100 to receive power from the external power network 10 for the discharge test of the test power storage device 100 when the test power storage device 100 does not reach the preset cut-off voltage.

In step S300, the control unit 300 may repeat the monitoring (S100) when the state of charge of the auxiliary power storage device 200 is not the complete state of charge (S301). The control unit 300 may then perform again the performing of the charge test (S200) and the performing of the discharge test (S300).

In step S300, the control unit 300 may discharge remaining power of the test power storage device 100 by bypassing the auxiliary power storage device 200 (S310) when the state of charge of the auxiliary power storage device 200 is the complete state of charge (S301).

In step S300, the control unit 300 may either proceed to the monitoring (S100) or proceed to step S310 to end the charge/discharge test based on the state of charge of the auxiliary power storage device 200 (in S301).

The present disclosure may include a computer-readable recording medium storing a computer program for performing the secondary battery charge/discharge test method. The secondary battery charge/discharge test method of the present disclosure may also be implemented in the form of a recording medium including a computer-executable instruction, such as a program module executed by a computer. Computer-readable medium may be any available medium that may be accessed by the computer, and may include all of a volatile or nonvolatile medium and a removable or non-removable medium. The computer-readable medium may also include a computer storage medium. The computer storage medium may include all of the volatile or nonvolatile medium and the removable or non-removable medium, which are implemented in any method or technology for storing information such as a computer-readable instruction, a data structure, a program module, or other data.

The present disclosure may be widely applied to a green technology field such as an electric vehicle, a battery charging station, and solar and wind power generation using the battery. In addition, the present disclosure may be used in an eco-friendly electric vehicle, a hybrid vehicle, or the like to prevent climate change by suppressing air pollution and greenhouse gas emissions.

As set forth above, according to an embodiment of the present disclosure, it is possible to reduce the total amount of power used in the secondary battery charge/discharge test by recycling the electric energy discarded during the discharge in the secondary battery charge/discharge test.

It is also possible to reduce the dependence on the external power to thus reduce the greenhouse gas emissions.

The content described above is only an example to which a principle of the present disclosure is applied, and may further include other configurations within the scope of the present disclosure.

What is claimed is:

1. A secondary battery charge/discharge test system comprising:
a test power storage device for charging or discharging a plurality of test secondary batteries;
an auxiliary power storage device for charging the test power storage device by discharging power stored therein or being charged using power discharged by the test power storage device; and
a control unit for controlling the charge or discharge of each of the auxiliary power storage device and the test power storage device based on the state of charge (SOC) or cut-off voltage of the auxiliary power storage device.

2. The system of claim 1, wherein the control unit stops the discharge of the auxiliary power storage device and charges the auxiliary power storage device by using power from an external power network when the state of charge of the auxiliary power storage device is less than a set value.

3. The system of claim 1, wherein the control unit charges the test power storage device by discharging the auxiliary power storage device when the state of charge of the auxiliary power storage device is the set value or more.

4. The system of claim 3, wherein the control unit stops the discharge of the auxiliary power storage device and charges the auxiliary power storage device by discharging the test power storage device when the auxiliary power storage device reaches the preset discharge cut-off voltage.

5. The system of claim 4, wherein the control unit charges the test power storage device to the preset charge cut-off voltage of the test power storage device by using power of the external power network, and then charges the auxiliary power storage device by discharging the test power storage device.

6. The system of claim 4, wherein the control unit charges the auxiliary power storage device by discharging the test power storage device when the state of charge of the auxiliary power storage device is the set value or more of the state of charge and less than a complete state of charge.

7. The system of claim 6, wherein the control unit discharges remaining power of the test power storage device by bypassing the auxiliary power storage device when the state of charge of the auxiliary power storage device is the complete state of charge.

8. The system of claim 4, wherein the control unit stops the discharge of the auxiliary power storage device and charges the auxiliary power storage device by discharging the test power storage device when the auxiliary power storage device does not reach the preset discharge cut-off voltage and the state of charge of the auxiliary power storage device is not a complete discharge state.

9. The system of claim 8, wherein the control unit charges the auxiliary power storage device using the external power network when the auxiliary power storage device does not reach the preset cut-off voltage and the state of charge of the auxiliary power storage device is the complete discharge state.

10. A secondary battery charge/discharge test method, in which a charge/discharge test of a test power storage device is performed by connecting the test power storage device including a plurality of test secondary batteries to a separate auxiliary power storage device, and controlling, by a control unit, the charge and discharge of each of the test power storage device and the auxiliary power storage device, the method comprising:
monitoring a state of charge of the auxiliary power storage device;
performing the charge test of charging the test power storage device by discharging the auxiliary power storage device when the state of charge of the auxiliary power storage device is a set value or more of the state of charge; and
performing the discharge test of charging the auxiliary power storage device by discharging the test power storage device when the auxiliary power storage device reaches the preset cut-off voltage in the charge test.

11. The method of claim 10, wherein in the monitoring,
the auxiliary power storage device is charged to the set value or more of the state of charge by using power of an external power network when the state of charge of the auxiliary power storage device is less than the set value.

12. The method of claim 10, wherein in the performing of the discharge test,
the auxiliary power storage device is charged using the external power network when the auxiliary power storage device does not reach the preset cut-off voltage and is in a complete discharge state.

13. The method of claim 10, wherein in the performing of the discharge test,
the test power storage device is charged using power from the external power network when the test power storage device does not reach its preset cut-off voltage, and the auxiliary power storage device is then charged by discharging the test power storage device.

14. The method of claim 10, wherein in the performing of the discharge test,
the monitoring is repeated when the state of charge of the auxiliary power storage device is not a complete state of charge.

15. The method of claim 10, wherein in the performing of the discharge test,
remaining power of the test power storage device is discharged by bypassing the auxiliary power storage device when the state of charge of the auxiliary power storage device is a complete state of charge.
